(19) United States
(12) Patent Application Publication
(10) Pub. No.: US 2024/0063042 A1
(43) Pub. Date: Feb. 22, 2024

(54) SUBSTRATE TRANSFER DEVICE

(71) Applicant: SEMES CO., LTD., Cheonan-si (KR)

(72) Inventors: Kiwon HAN, Cheonan-si (KR); Kyobong KIM, Cheonan-si (KR); Sang-oh KIM, Cheonan-si (KR)

(73) Assignee: SEMES CO., LTD., Cheonan-si (KR)

(21) Appl. No.: 18/363,962

(22) Filed: Aug. 2, 2023

(30) Foreign Application Priority Data
Aug. 19, 2022 (KR) 10-2022-0103855

(51) Int. Cl. H01L 21/677; H01L 21/67

(52) U.S. Cl. CPC H01L 21/67766; H01L 21/67259

(57) ABSTRACT

A transfer part may move the first substrate and the second substrate such that the first substrate and the second substrate are overlapped with each other when the transport transfers the first substrate and the second substrate. The detection part may detect a first position of the first substrate and a first position of the second substrate at points apart from a reference point where the first substrate and the second substrate are overlapped by first distances, and may detect respective second positions at points apart from the reference point by second distances. A control part may control movements of the first and the second substrates by the transfer part based on output of the detection part.

### CROSS-REFERENCE TO RELATED APPLICATION

This application claims priority to Korean Patent Application No. 10-2022-0103855 filed on Aug. 19, 2022 in the Korean Intellectual Property Office (KIPO), the contents of which are herein incorporated by reference in its entirety.

### BACKGROUND

### 1. Field

Example embodiments of the invention relate to a substrate transfer device. More particularly, example embodiments of the invention relate to a substrate transfer device capable of simultaneously transferring a plurality of substrates.

### 2. Related Technology

In processes for manufacturing an integrated circuit device such as a semiconductor device, a substrate is very frequently transferred among various apparatuses for performing such processes. In this case, the substrate placed on a transfer device may be detected such that the substrate may be moved to a previously set position in accordance with the results of detection if the position of the substrate is deviated from the previously set position.

Recently, in order to efficiently manufacture the integrated circuit devices, two substrates may be simultaneously transferred among the apparatuses. However, it may be substantially impossible to simultaneously detect the positions of the two substrates while simultaneously transferring the two substrates among the apparatuses because the positions of the two substrates may be interfered with each other. Thus, when the two substrates are simultaneously transferred, the position of one substrate may be detected, and then the position of the other substrate may be detected. However, such a detection process may not improve the productivity of the integrated circuit devices.

### SUMMARY

It is an object of the invention to provide a substrate transfer device which may simultaneously transfer a plurality of substrates and may simultaneously detect the positions of the plurality of substrates.

According to an aspect of the invention, there is provided a substrate transfer device. The substrate transfer device may include a transfer part, a detection part and a control part. The transfer part may include a first transfer member configured to transfer a first substrate and a second transfer member configured to transfer a second substrate. The transfer part may move the first substrate and the second substrate such that the first substrate and the second substrate may be overlapped with each other when the transport transfers the first substrate and the second substrate. The detection part may be configured to simultaneously detect a position of the first substrate on the first transfer member and a position of the second substrate on the second transfer member. The detection part may detect a first position of the first substrate and a first position of the second substrate at points apart from a reference point where the first substrate and the second substrate are overlapped by first distances, and may detect a second position of the first substrate and a second position of the second substrate at points apart from the reference point by second distances. The control part may be configured to control the transfer part. The control part may control movements of the first and the second substrates by the transfer part so that the detection part may detect the first position of the first substrate at the point apart from the reference point by the first distance, and simultaneously detects the second position of the second substrate at the point apart from the reference point by the second distance. The control part may control movements of the first and the second substrates by the transfer part such that the detection part may detect the second position of the first substrate at the point apart from the reference point by the second distance, and simultaneously may detect the first position of the second substrate at the point apart from the reference point by the first distance.

In example embodiments, the first position of the first substrate and the first position of the second substrate may correspond to one end portion of the first substrate and one end portion of the second substrate, respectively. The second position of the first substrate and the second position of the second substrate may correspond to the other end portion of the first substrate and the other end portion of the second substrate, respectively.

In some example embodiments, the first position of the first substrate and the first position of the second substrate may correspond to two peripheral portions of one side of the first substrate and two peripheral portions of one side of the second substrate, respectively. The second position of the first substrate and the second position of the second substrate may correspond to two peripheral portions of the other side of the first substrate and two peripheral portions of the other side of the second substrate, respectively.

In example embodiments, the point apart from the reference point by the first distance may be a point away from the reference point by a distance +d, and the point apart from the reference point by the second distance may be a point away from the reference point by a distance −d.

In example embodiments, the detection part may include a light emitting member and a light receiving member disposed to be faced with each other in a vertical direction centering a path along with the first and the second substrates.

In example embodiments, the control part may control the first and the second transfer members based on the positions of the first and the second substrates detected by the detection part such that the positions of the first and the second substrates are moved to previously set positions.

According to another aspect of the invention, there is provided a substrate transfer device. The substrate transfer device may include a transfer part, a detection part and a control part. The transfer part may include a first transfer member configured to transfer a first substrate and a second transfer member configured to transfer a second substrate. The first transfer member and the second transfer member may be configured to move the first substrate and the second substrate in a horizontal direction, respectively. The transfer part may move the first substrate and the second substrate such that the first substrate and the second substrate may be overlapped with each other when the transport transfers the first substrate and the second substrate. The detection part may be configured to simultaneously detect a position of the first substrate on the first transfer member and a position of the second substrate on the second transfer member. The detection part may detect a first position of the first substrate and a first position of the second substrate at points apart from a reference point where the first substrate and the second substrate are overlapped by first distances, and the detection part may detect a second position of the first substrate and a second position of the second substrate at points apart from the reference point by second distances. The control part may be configured to control movements of the first and the second substrates by the first transfer member and the second transfer member. The control part may control the first and the second transfer members so that the detection part detects the first position of the first substrate at the point apart from the reference point by the first distance, and simultaneously may detect the second position of the second substrate at the point apart from the reference point by the second distance. The control part may control the first and the second transfer members such that the detection part detects the second position of the first substrate at the point apart from the reference point by the second distance, and simultaneously may detect the first position of the second substrate at the point apart from the reference point by the first distance.

In example embodiments, the first position of the first substrate and the first position of the second substrate may correspond to one end portion of the first substrate and one end portion of the second substrate, respectively. The second position of the first substrate and the second position of the second substrate may correspond to the other end portion of the first substrate and the other end portion of the second substrate, respectively.

In some example embodiments, the first position of the first substrate and the first position of the second substrate may correspond to two peripheral portions of one side of the first substrate and two peripheral portions of one side of the second substrate, respectively. The second position of the first substrate and the second position of the second substrate may correspond to two peripheral portions of the other side of the first substrate and two peripheral portions of the other side of the second substrate, respectively.

In example embodiments, the point apart from the reference point by the first distance may be a point away from the reference point by a distance +d, and the point apart from the reference point by the second distance may be a point away from the reference point by a distance −d.

In example embodiments, the detection part may include a light emitting member and a light receiving member disposed to be faced with each other in a vertical direction centering a path along with the first and the second substrates.

In example embodiments, the control part may control the first and the second transfer members based on the positions of the first and the second substrates detected by the detection part such that the positions of the first and the second substrates may be moved to previously set positions.

According to an aspect of the invention, there is provided a substrate transfer device. The substrate transfer device may include a transfer part, a detection part and a control part. The transfer part may include a first transfer member configured to transfer a first substrate and a second transfer member configured to transfer a second substrate. The first transfer member and the second transfer member may be configured to rotate the first substrate and the second substrate, respectively, and wherein the transfer part moves the first substrate and the second substrate such that the first substrate and the second substrate may be overlapped with each other when the transport transfers the first substrate and the second substrate. The detection part may be configured to simultaneously detect a position of the first substrate on the first transfer member and a position of the second substrate on the second transfer member. The detection part may detect a first position of the first substrate and a first position of the second substrate at points apart from a reference point where the first substrate and the second substrate may be overlapped by first distances, and the detection part may detect a second position of the first substrate and a second position of the second substrate at points apart from the reference point by second distances. The control part may be configured to control movements of the first and the second substrates by the first transfer member and the second transfer member. The control part may control the first and the second transfer members so that the detection part may detect the first position of the first substrate at the point apart from the reference point by the first distance, and simultaneously may detect the second position of the second substrate at the point apart from the reference point by the second distance. The control part may control the first and the second transfer members such that the detection part may detect the second position of the first substrate at the point apart from the reference point by the second distance, and simultaneously may detect the first position of the second substrate at the point apart from the reference point by the first distance.

In example embodiments, the first position of the first substrate and the first position of the second substrate may correspond to one end portion of the first substrate and one end portion of the second substrate, respectively. The second position of the first substrate and the second position of the second substrate may correspond to the other end portion of the first substrate and the other end portion of the second substrate, respectively.

In some example embodiments, the first position of the first substrate and the first position of the second substrate may correspond to two peripheral portions of one side of the first substrate and two peripheral portions of one side of the second substrate, respectively. The second position of the first substrate and the second position of the second substrate may correspond to two peripheral portions of the other side of the first substrate and two peripheral portions of the other side of the second substrate, respectively.

In example embodiments, the point apart from the reference point by the first distance may be a point away from the reference point by a distance +d and the point apart from the reference point by the second distance may be a point away from the reference point by a distance −d.

In example embodiments, the detection part may include a light emitting member and a light receiving member disposed to be faced with each other in a vertical direction centering a path along with the first and the second substrates.

In example embodiments, the control part may control the first and the second transfer members based on the positions of the first and the second substrates detected by the detection part such that the positions of the first and the second substrates may be moved to previously set positions.

In some example embodiments, the first and the second transfer members may rotate the first and the second substrates centering a common axis, respectively. The first and the second transfer members may move the first and the second substrates in a horizontal direction.

In some example embodiments, each of the first transfer member and the second transfer member may have a multijoint structure.

According to example embodiments, the substrate transfer device may simultaneously detect the positions of the plurality of substrate while transferring the plurality of substrate in the horizontal direction and/or in the vertical direction. Additionally, the substrate transfer device may simultaneously detect the positions of the plurality of substrate while transferring the plurality of substrate by rotating the plurality of substrates. Therefore, the substrate transfer device may be employed in processes for manufacturing various semiconductor devices such as a memory device, a non-memory device, a system semiconductor device, etc.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a schematic cross-sectional view illustrating a substrate transfer device in accordance with example embodiments of the invention.

FIG. 2 is a schematic plane view illustrating the substrate transfer device in accordance with example embodiments of the invention.

FIG. 3 is a schematic cross-sectional view illustrating the operation of the substrate transfer device in accordance with example embodiments of the invention.

FIG. 4 is a schematic perspective view illustrating a substrate transfer device in accordance with some example embodiments of the invention.

FIG. 5 is a schematic plane view illustrating the substrate transfer device in accordance with other example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, it will be described a substrate transfer device according to example embodiments with reference to the accompanying drawings.

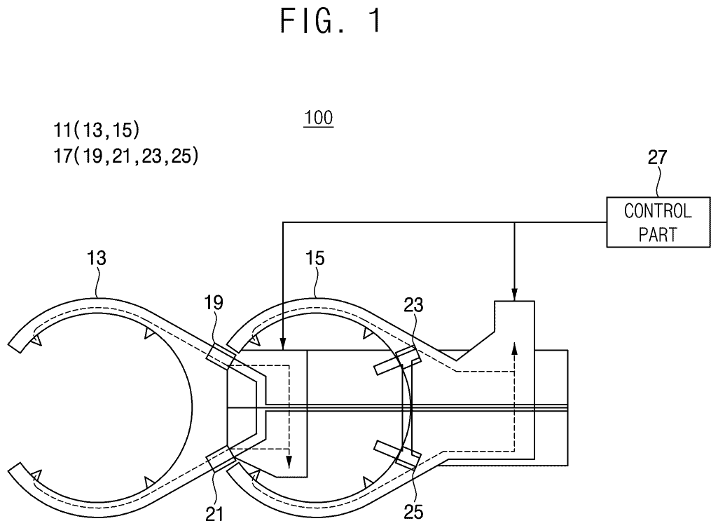

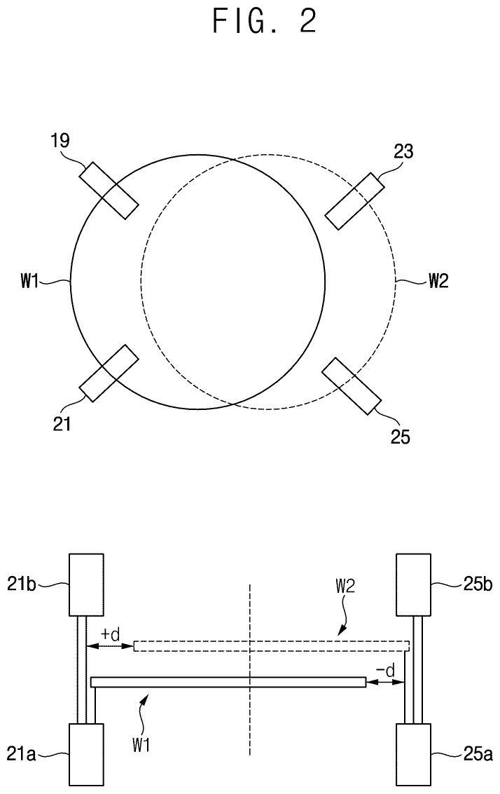

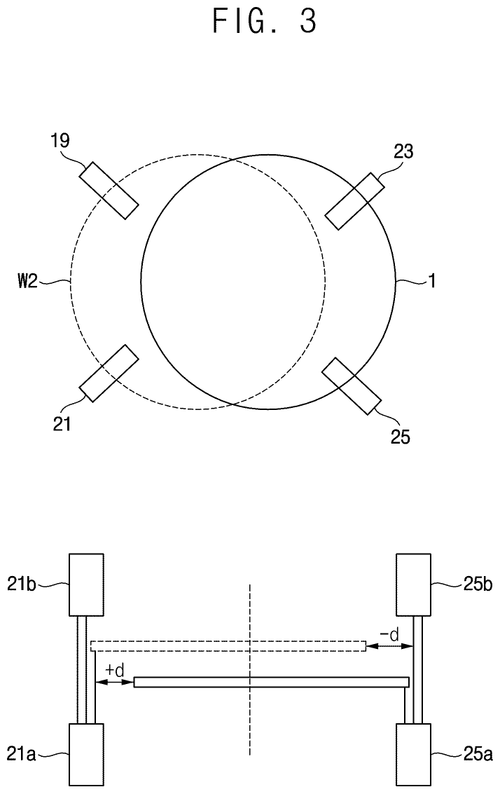

FIG. 1 is a schematic cross-sectional view illustrating a substrate transfer device in accordance with example embodiments of the invention. FIG. 2 is a schematic plane view illustrating the substrate transfer device in accordance with example embodiments of the invention. FIG. 3 is a schematic cross-sectional view illustrating the operation of the substrate transfer device in accordance with example embodiments of the invention.

Referring to FIG. 1 to FIG. 3, a substrate transfer device 100 according to example embodiments may be used to transfer a substrate in processes for manufacturing an integrated circuit device such as a semiconductor device. For example, the substrate transfer device 100 may be disposed among various substrate processing apparatuses for performing various processes on the substrate such that the substrate transfer device 100 may transfer the substrate among the substrate processing apparatuses. Alternatively, the substrate transfer device 100 may be installed in one or more substrate processing apparatus so that the substrate transfer device 100 transfer the substrate in the one or more substrate processing apparatus.

In example embodiments, when the substrate processing apparatus includes a coating device for providing a chemical liquid onto a substrate and a developing device for developing the chemical liquid coated on the substrate, the substrate transfer device 100 may transfer the substrate from an outside into the coating device, may transfer the substrate from the coating device into the developing device and/or may transfer the substrate from the developing device to the outside.

According to example embodiments, the substrate transfer device 100 may include a transfer part 11, a detection part 17 and a control part 27. The substrate transfer device 100 may simultaneously transfer a plurality of substrate among the substrate processing apparatuses and/or in the one or more substrate processing apparatus, and may simultaneously detect the positions of the plurality of substrate. For example, the substrate transfer device 100 may simultaneously detect the positions of two substrates while simultaneously transferring the two substrates.

If the substrate transfer device 100 simultaneously transfers the two substrates, the transfer part 11 may include a first transfer member 13 for transferring a first substrate and a second transfer member 15 for transferring a second substrate. In this case, the first transfer member 13 may have a structure substantially the same as that of the second transfer member 15.

In example embodiments, the transfer part 11 of substrate transfer device 100 may transfer the plurality of substrate in a substantially vertical direction, and also may transfer the plurality of substrate along a substantially horizontal direction. For example, the transfer part 11 may move the plurality of substrate along a Z-axis direction, and also may move the plurality of substrate in an X-axis direction or a Y-axis direction. In other words, the transfer part 11 may move the plurality of substrate along a first path (e.g., a path provided in the Z-axis direction) and a second path (e.g., a path provided in the X-axis direction or the Y-axis direction) substantially perpendicular to each other. Such transfer of the plurality of substrates may be performed among a plurality of substrate processing apparatuses and/or in more than one substrate processing apparatus.

When the transfer part 11 moves the substrates along the substantially horizontal direction, the first transfer member 13 and the second transfer member 15 may transfer the substrates along paths substantially overlapped with each other. For example, the first transfer member 13 and the second transfer member 15 may move the first substrate and the second substrate along the paths substantially overlapped with each other. In other words, the first and the second substrates transferred by the first and the second transfer members 13 and 15 may be moved along the paths at least partially overlapped with each other, respectively.

In example embodiments, each of the first transfer member 13 and the second transfer member 15 may include a hand holding the substrate thereon, an arm coupled to the hand, and a driving member for driving the hand and the arm. For example, the detailed configurations of the transfer part 11 having the first and the second transfer members 13 and 15 are described in Korean Patent Application Publication No. 2022-0094021 (the title of invention: Transfer unit and substrate processing apparatus having the same), which was assigned to the applicant and is incorporated herein by reference in its entirety.

Referring now to FIG. 1 to FIG. 3, the detection part 17 of the substrate transfer device 100 may substantially simultaneously detect the positions of the plurality of substrates. For example, the detection member 17 may simultaneously detect the position of the first substrate on the first transfer member 13 and the position of the second substrate on the second transfer member 15 while the first transfer member 13 and the second transfer member 15 transfer the first substrate and the second substrate, respectively.

According to example embodiments, the detection member 17 may detect the positions of the first and the second substrates based on a point wherein the first and the second substrates are substantially overlapped with each other (hereinafter, referred to as “a reference point”) while transferring the first and the second substrates. In this case, the detection part 17 may simultaneously identify a first position of the first substrate and a first position of the second substrate at points apart from the reference point by first distances. Additionally, the detection part 17 may simultaneously detect a second position of the first substrate and a second position of the second substrate at points away from the reference point by second distances. For example, the first position of the first substrate and the first position of the second substrate may correspond to one end portion of the first substrate and one end portion of the second substrate along one direction from the reference point, respectively. In addition, the second position of the first substrate and the second position of the second substrate may respectively correspond to the other end portion of the first substrate and the other end portion of the second substrate along the other direction from the reference point, respectively. In other words, the detection part 17 may not detect the reference point where the first and the second substrates are overlapped with each other. Instead, the detection part 17 may detect the points corresponding to the first positions of the first and the second substrate apart from the reference point by the first distances, and also may detect the points corresponding to the second positions of the first and the second substrate away from the reference point by the second distances.

In example embodiments, the detection member 17 may include a light emitting member and a light receiving member. In this case, the light emitting member and the light receiving member may be disposed such that the light emitting member and the light receiving member may be substantially faced with each other centering the paths wherein the substrates are transferred. For example, the light emitting member and the light receiving member may be vertically faced with each other centering the path. For example, the detailed configurations of the detection part 17 having the light emitting member and the light receiving member are described in Korean Registered Patent No. 10-1931061 (the title of invention: Substrate transfer apparatus, substrate transfer method and recording medium having recorded program for executing the substrate transfer method), which is incorporated herein by reference in its entirety.

In some example embodiments, the first position of the first substrate may correspond to one peripheral portion of the first substrate and the second position of the first substrate may correspond to another peripheral portion of the first substrate. Additionally, the first position of the second substrate may correspond to one peripheral portion of the second substrate and the second position of the second substrate may correspond to another peripheral portion of the second substrate.

In other example embodiments, the first position of the first substrate may correspond to two peripheral portions of one side of the first substrate and the second position of the first substrate may correspond to two peripheral portions of the other side of the first substrate. Similarly, the first position of the second substrate may correspond to two peripheral portions of one side of the second substrate and the second position of the second substrate may correspond to two peripheral portions of the other side of the second substrate. For example, if each of the first and the second substrates is a circular wafer, the first and the second positions of the first substrate may respectively correspond to four peripheral portions of first wafer apart from each other by distances of about 90° based on a central axis of the first wafer. In addition, the first and the second positions of the second substrate may respectively correspond to four peripheral portions of second wafer apart from each other by distances of about 90° based on a central axis of the second wafer.

As described in the above-mentioned Korean Registered Patent No. 10-1931061, the detection part 17 of the substrate transfer device 100 may not be adjacent to both end portions of the first substrate as well as both end portions of the second substrate. That is, the detection part 17 may not identify the positions corresponding to the end portions of the first and the second substrates. Instead, the detection part 17 may detect the first and the second positions of the first and the second substrates at the points apart from the reference point by the first distances and at the points away from the reference point by the second distances, respectively. To this end, the detection part 17 may be adjacent to the points apart from the reference point by the first distance and the points away from the reference point by the second distance. In other words, the detection part 17 may detect the positions of the first and the second substrates at the points away the points where the first substrate and the second substrate are overlapped with each other by predetermined distances (i.e., the first distances and the second distances).

As illustrated in FIG. 2 and FIG. 3, the detection part 17 may be adjacent to the points away from the reference point (i.e., the point in which the first and the second substrates are overlapped) by the first distances, and such points may be points apart from the reference point by distances +d. Further, the points away from the reference point by the second distances may be points apart from the reference point by distances −d. Therefore, the detection part 17 may be disposed adjacent to the points away from the reference point by the distances +d, in a first direction, and also may be disposed adjacent to the points apart from the reference point by the distances −d in a second direction. Here, the first direction may be substantially opposed to the second direction.

As described above, the detection part 17 of the substrate transfer device 100 may be disposed at the position apart from one end portion of the first substrate and one end portion of the second substrate by the distance of +d in an +X-axis direction. Further, the detection part 17 may be disposed at the position apart from the other end portion of the first substrate and the other end portion of the second substrate by the distance of −d in a −X-axis direction.

To simultaneously detect the positions of the two substrate by using the detection part 17, the movements of the first and the second substrates may be properly controlled such that the detection part may precisely detect the positions of the first and the second substrates while thee first and the second substrates are transferred by the transfer part 11.

The control part 17 may control the transfer part 11 such that the first transfer member 13 and the second transfer member may adjust the entire movements of the first and the second substrates. Further, the control part 17 may control the transfer part 11 so that the first transfer member 13 and the second transfer member may adjust the minute movements of the first and the second substrates. Therefore, the detection part 17 may simultaneously and correctly detect the positions of the first and the second substrates while transferring the first and the second substrates. For example, the detection part 17 may simultaneously detect the second position of the second substrate when the detection part 17 detects the first position of the first substrate. In addition, the detection part 17 may simultaneously detect the first position of the second substrate when the detection part 17 detects the second position of the first substrate. In this case, the control part 27 may enable the detection part 17 to simultaneously and correctly detect the first and the second positions of the first and the second substrates by controlling the movements of the first and the second substrates through the transfer part 11. In this case, the control part 27 may adjust the movements of the first and the substrates through the transfer part 11, and thus the detection part 17 may simultaneously and correctly detect the first and the second positions of the first and the second substrates. For example, the control part 27 may control the transfer part 11 such that the detection part 17 may detect the first position of the first substrate at the position apart from the reference point by the first distance, and simultaneously may detect the second position of the second substrate at the point away from the reference point by the second distance. Further, the control part 27 may control the transfer part 11 so that the detection part 17 may detect the second position of the first substrate at the position apart from the reference point by the second distance, and simultaneously may detect the first position of the second substrate at the point away from the reference point by the first distance. In other words, the control part 27 may control the operation of the first transfer member 13 and the operation of the second transfer member 15 so that the first substrate and the second substrate may be placed at the predetermined positions, respectively. Here, the control part 27 may control the operation of the first transfer 13 such that one end portion of the first substrate may be positioned toward the detection part 17 disposed adjacent to the point apart from the reference point by the first distance. Simultaneously, the control part 27 may control the operation of the second transfer 15 so that the other end portion of the second substrate may be positioned toward the detection part 17 disposed adjacent to the point apart from the reference point by the second distance. Therefore, the detection part 17 may simultaneously detect one end portion of the first substrate and the other end portion of the second substrate. Further, the control part 27 may control the operation of the first transfer 13 so that the other end portion of the first substrate may be positioned toward the detection part 17 disposed adjacent to the point apart from the reference point by the second distance. Simultaneously, the control part 27 may control the operation of the second transfer 15 such that one end portion of the second substrate may be positioned toward the detection part 17 disposed adjacent to the point apart from the reference point by the first distance. As a result, the detection part 17 may simultaneously detect the other end portion of the first substrate and one end portion of the second substrate.

Hereinafter, a method for simultaneously detecting the positions of the two substrates when the two substrates are simultaneously transferred with reference to FIG. 2 and FIG. 3.

As illustrated in FIG. 2 and FIG. 3, each of a first substrate W1 and a second substrate W2 may be a circular wafer. The detection part 17 may include a first detection member 19, a second detection member 21, a third detection member 23 and a fourth detection member 25. The first and the second detection members 19 and 21 may be disposed adjacent to the points away from the point where the first substrate W1 and the second substrate W2 are overlapped with each other (i.e., the reference point) by the distance +d along the +X-axis direction. The third and the fourth detection members 23 and 25 may be disposed adjacent to the points apart from the reference point by the distance −d along the −X-axis direction. Here, each of the first and the second detection members 19 and 21 and each of the third and the fourth detection members 23 and 25 may be respectively faced along the Y-axis direction.

As illustrated in FIG. 2, using the transfer part 11 and the control part 27, one end portion of the first substrate W1 may be spaced apart from the reference point by the distance +d and simultaneously the other end portion of the second substrate W2 may be separated from the reference point by the distance −d. Thus, one end portion of the first substrate W1 may be positioned toward the first and the second detection members 19 and 21, and the other end portion of the second substrate W2 may be positioned toward the third and the fourth detection members 23 and 25. At this time, using the first and the second detection members 19 and 21, the position of one end portion of the first substrate W1 may be detected. Simultaneously, using the third and the fourth detection members 23 and 25, the position of the other end portion of the second substrate W2 may be detected. Specifically, the position of one end portion of the first substrate W1 and the position of the other end portion of the second substrate W2 may be simultaneously detected using light emitting members 21a and 25a and light receiving members 21b and 25b disposed along the Z-axis direction.

After detecting the position of one end portion of the first substrate W1 and the position of the other end portion of the second substrate W2 using the first to the fourth detection members 19, 21, 23 and 25, one end portion of the second substrate W2 may be spaced apart from the reference point by the distance +d and the other end portion of the first substrate W1 may be separated from the reference point by the distance −d as illustrated in FIG. 3. Thus, one end portion of the second substrate W2 may be positioned toward the first and the second detection members 19 and 21, and the other end portion of the first substrate W1 may be positioned toward the third and the fourth detection members 23 and 25. At this time, using the first and the second detection members 19 and 21, the position of one end portion of the second substrate W2 may be detected, and the position of the other end portion of the first substrate W1 may be simultaneously detected. Specifically, the position of the other end portion of the first substrate W1 and the position of one end portion of the second substrate W2 may be simultaneously detected using light emitting members 21a and 25a and light receiving members 21b and 25b disposed in the Z-axis direction.

When the first substrate W1 and the second substrate W2 are simultaneously transferred using the substrate transfer device 100 according to example embodiments, the positions of the first substrate W1 and the second substrate W2 may be simultaneously detected through the arrangement of the detection part 17, the cross movement between the first substrate W1 and the second substrate W2 using the transfer part 11 and the control part 27, etc. Alternatively, the positions of the first substrate W1 and the second substrate W2 may be simultaneously detected through the adjustment of the position of the detection part 17 and the control of the position of the transfer part 11.

In example embodiments, the substrate transfer device 100 may adjust the positions of the first and the second substrates W1 and W2 to previously set positions relative to the first and the second transfer members 13 and 15 based on the results of simultaneous detections of the first and the second substrates W1 and W2. To this end, the entire movement of the transfer part 11 including the first and the second transfer members 13 and 15 may be controlled, and also the movements of the first and the second transfer members 13 and 15 holding the first and the second substrates may be precisely adjusted.

According to example embodiments, the transfer part 11 of the substrate transfer device 100 may transfer the plurality of substrates in various paths along the X-axis direction, the Y-axis direction and/or the Z-axis direction. For example, the first and the second substrates W1 and W2 may be moved toward the first and the second detection members 19 and 21 and toward the third and the fourth detection members 23 and 25 when the positions of the first and the second substrates W1 and W2 are detected. In this case, as illustrated in FIG. 2 and FIG. 3, the first and the second substrates W1 and W2 may move toward the first and the second detection members 19 and 21 by the distance +d along the +X-axis direction. Additionally, the first and the second substrates W1 and W2 may move toward the third and the fourth detection members 23 and 25 by the distance −d along the −X-axis direction. Such operation of the transfer part 11 is described in the above-mentioned Korean Patent Application Publication No. 2022-00094021.

In some example embodiments, the transfer part 11 having the first and the second transfer members 13 and 15 may rotate the first and the second substrates W1 and W2 as well as may move the first and the second substrates W1 and W2 in the horizontal direction and/or the vertical direction.

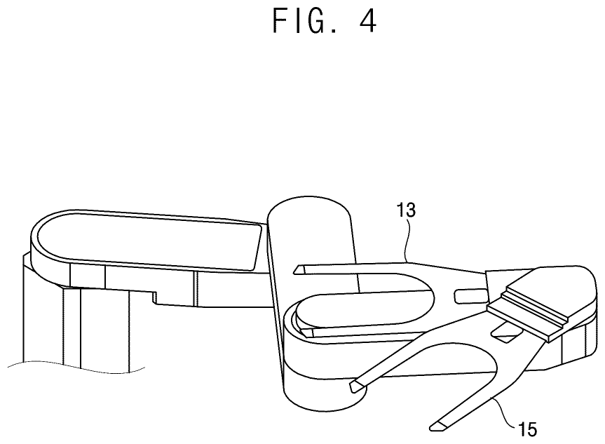

FIG. 4 is a schematic perspective view illustrating a substrate transfer device in accordance with some example embodiments of the invention.

As illustrated in FIG. 4, the transfer part 11 of the substrate transfer device may include a first transfer member 13 and a second transfer member 15 which may rotatable centering a common axis. Each of the first transfer member 13 and the second transfer member 15 may have a horizontal ally extending multijoint structure. In this case, the first transfer member 13 and the second transfer member 15 may be disposed in the vertical direction. Therefore, the first transfer members 13 and the second transfer member 15 may rotate a first substrate and a second substrate, respectively. Further, as described above, the first and the second transfer members 13 and 15 may respectively move the first and the second substrates in the X-axis direction and/or the Y-axis direction. For example, the transfer part 11 may transfer the first and the second substrates by rotating the first and the second substrates using the first and the second transfer members 13 and 15 in one or more substrate processing apparatus. Among the plurality of substrate processing apparatuses, the transfer part 11 may transfer the first and the second substrates using the first and the second transfer members 13 and 15 in the horizontal direction and/or the vertical direction. However, the operation of the transfer part 11 of the invention may not be limited to such operations. In the substrate transfer device including the configuration illustrated in FIG. 4, the first and the second transfer members 13 and 15 may transfer the first and the second substrates along the horizontal direction even though the positions of the first and the second substrates are detected.

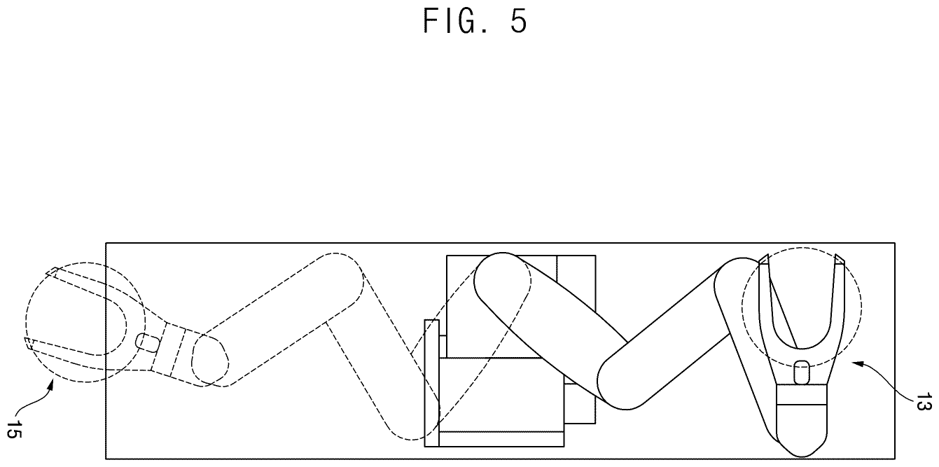

FIG. 5 is a schematic plane view illustrating the substrate transfer device in accordance with other example embodiments of the invention.

Referring to FIG. 5, the transfer part 11 of the substrate transfer device may include a first transfer member 13 and a second transfer member 15 each of which may include an arm having a multijoint structure. In this case, each of the arms of the first and the second transfer members 13 and 15 may have the multijoint structure extending in the horizontal direction. For example, the arm may have a joint structure including 3 joints. Such arms having the multijoint structure may transfer a plurality of substrates in the horizontal direction. Further, the first and the second transfer members 13 and 15 including the arms of the multijoint structures may rotate the plurality of substrates, for example, two substrates. As described above, the first and the second transfer members 13 and 15 may respectively move the plurality of substrates in the X-axis direction and/or the Y-axis direction. For example, the transfer part 11 may transfer the plurality of substrates by rotating the plurality of substrates using the first and the second transfer members 13 and 15 in one or more substrate processing apparatus. Further, among the plurality of substrate processing apparatuses, the transfer part 11 may transfer the plurality of substrates using the first and the second transfer members 13 and 15 in the horizontal direction and/or the vertical direction. In the substrate transfer device including the configuration illustrated in FIG. 5, the first and the second transfer members 13 and 15 may transfer the plurality of substrates along the horizontal direction even though the positions of the plurality of substrates are detected.

As discussed above, the substrate transfer device according to example embodiments may simultaneously detect the positions of the plurality of substrate while transferring the plurality of substrate in the horizontal direction and/or in the vertical direction. Further, the substrate transfer device may simultaneously detect the positions of the plurality of substrate while transferring the plurality of substrate by rotating the plurality of substrates.

According to example embodiments of the invention, the substrate transfer device may be employed in processes for manufacturing various semiconductor devices such as a memory device, a non-memory device, a system semiconductor device, etc. Particularly, the substrate transfer device may be advantageously used to circular wafer for manufacturing an integrated circuit device.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A substrate transfer device comprising:
a transfer part including a first transfer member configured to transfer a first substrate and a second transfer member configured to transfer a second substrate, wherein the transfer part moves the first substrate and the second substrate such that the first substrate and the second substrate are overlapped with each other when the transport transfers the first substrate and the second substrate;
a detection part configured to simultaneously detect a position of the first substrate on the first transfer member and a position of the second substrate on the second transfer member, wherein the detection part detects a first position of the first substrate and a first position of the second substrate at points apart from a reference point where the first substrate and the second substrate are overlapped by first distances, and the detection part detects a second position of the first substrate and a second position of the second substrate at points apart from the reference point by second distances; and
a control part configured to control the transfer part, wherein the control part controls movements of the first and the second substrates by the transfer part so that the detection part detects the first position of the first substrate at the point apart from the reference point by the first distance, and simultaneously detects the second position of the second substrate at the point apart from the reference point by the second distance, and wherein the control part controls movements of the first and the second substrates by the transfer part such that the detection part detects the second position of the first substrate at the point apart from the reference point by the second distance, and simultaneously detects the first position of the second substrate at the point apart from the reference point by the first distance.

2. The substrate transfer device of claim 1, wherein the first position of the first substrate and the first position of the second substrate correspond to one end portion of the first substrate and one end portion of the second substrate, respectively, and wherein the second position of the first substrate and the second position of the second substrate correspond to the other end portion of the first substrate and the other end portion of the second substrate, respectively.

3. The substrate transfer device of claim 1, wherein the first position of the first substrate and the first position of the second substrate correspond to two peripheral portions of one side of the first substrate and two peripheral portions of one side of the second substrate, respectively, and wherein the second position of the first substrate and the second position of the second substrate correspond to two peripheral portions of the other side of the first substrate and two peripheral portions of the other side of the second substrate, respectively.

4. The substrate transfer device of claim 1, wherein the point apart from the reference point by the first distance is a point away from the reference point by a distance +d and the point apart from the reference point by the second distance is a point away from the reference point by a distance −d.

5. The substrate transfer device of claim 1, wherein the detection part includes a light emitting member and a light receiving member disposed to be faced with each other in a vertical direction centering a path along with the first and the second substrates.

6. The substrate transfer device of claim 1, wherein the control part controls the first and the second transfer members based on the positions of the first and the second substrates detected by the detection part such that the positions of the first and the second substrates are moved to previously set positions.

7. A substrate transfer device comprising:
a transfer part including a first transfer member configured to transfer a first substrate and a second transfer member configured to transfer a second substrate, wherein the first transfer member and the second transfer member are configured to move the first substrate and the second substrate in a horizontal direction, respectively, and wherein the transfer part moves the first substrate and the second substrate such that the first substrate and the second substrate are overlapped with each other when the transport transfers the first substrate and the second substrate;
a detection part configured to simultaneously detect a position of the first substrate on the first transfer member and a position of the second substrate on the second transfer member, wherein the detection part detects a first position of the first substrate and a first position of the second substrate at points apart from a reference point where the first substrate and the second substrate are overlapped by first distances, and the detection part detects a second position of the first substrate and a second position of the second substrate at points apart from the reference point by second distances; and
a control part configured to control movements of the first and the second substrates by the first transfer member and the second transfer member, wherein the control part controls the first and the second transfer members so that the detection part detects the first position of the first substrate at the point apart from the reference point by the first distance, and simultaneously detects the second position of the second substrate at the point apart from the reference point by the second distance, and wherein the control part controls the first and the second transfer members such that the detection part detects the second position of the first substrate at the point apart from the reference point by the second distance, and simultaneously detects the first position of the second substrate at the point apart from the reference point by the first distance.

8. The substrate transfer device of claim 7, wherein the first position of the first substrate and the first position of the second substrate correspond to one end portion of the first substrate and one end portion of the second substrate, respectively, and wherein the second position of the first substrate and the second position of the second substrate correspond to the other end portion of the first substrate and the other end portion of the second substrate, respectively.

9. The substrate transfer device of claim 7, wherein the first position of the first substrate and the first position of the second substrate correspond to two peripheral portions of one side of the first substrate and two peripheral portions of one side of the second substrate, respectively, and wherein the second position of the first substrate and the second position of the second substrate correspond to two peripheral portions of the other side of the first substrate and two peripheral portions of the other side of the second substrate, respectively.

10. The substrate transfer device of claim 7, wherein the point apart from the reference point by the first distance is a point away from the reference point by a distance +d and the point apart from the reference point by the second distance is a point away from the reference point by a distance −d.

11. The substrate transfer device of claim 7, wherein the detection part includes a light emitting member and a light receiving member disposed to be faced with each other in a vertical direction centering a path along with the first and the second substrates.

12. The substrate transfer device of claim 7, wherein the control part controls the first and the second transfer members based on the positions of the first and the second substrates detected by the detection part such that the positions of the first and the second substrates are moved to previously set positions.

13. A substrate transfer device comprising:
a transfer part including a first transfer member configured to transfer a first substrate and a second transfer member configured to transfer a second substrate, wherein the first transfer member and the second transfer member are configured to rotate the first substrate and the second substrate, respectively, and wherein the transfer part moves the first substrate and the second substrate such that the first substrate and the second substrate are overlapped with each other when the transport transfers the first substrate and the second substrate;
a detection part configured to simultaneously detect a position of the first substrate on the first transfer member and a position of the second substrate on the second transfer member, wherein the detection part detects a first position of the first substrate and a first position of the second substrate at points apart from a reference point where the first substrate and the second substrate are overlapped by first distances, and the detection part detects a second position of the first substrate and a second position of the second substrate at points apart from the reference point by second distances; and
a control part configured to control movements of the first and the second substrates by the first transfer member and the second transfer member, wherein the control part controls the first and the second transfer members so that the detection part detects the first position of the first substrate at the point apart from the reference point by the first distance, and simultaneously detects the second position of the second substrate at the point apart from the reference point by the second distance, and wherein the control part controls the first and the second transfer members such that the detection part detects the second position of the first substrate at the point apart from the reference point by the second distance, and simultaneously detects the first position of the second substrate at the point apart from the reference point by the first distance.

14. The substrate transfer device of claim 13, wherein the first position of the first substrate and the first position of the second substrate correspond to one end portion of the first substrate and one end portion of the second substrate, respectively, and wherein the second position of the first substrate and the second position of the second substrate correspond to the other end portion of the first substrate and the other end portion of the second substrate, respectively.

15. The substrate transfer device of claim 13, wherein the first position of the first substrate and the first position of the second substrate correspond to two peripheral portions of one side of the first substrate and two peripheral portions of one side of the second substrate, respectively, and wherein the second position of the first substrate and the second position of the second substrate correspond to two peripheral portions of the other side of the first substrate and two peripheral portions of the other side of the second substrate, respectively.

16. The substrate transfer device of claim 13, wherein the point apart from the reference point by the first distance is a point away from the reference point by a distance +d and the point apart from the reference point by the second distance is a point away from the reference point by a distance −d.

17. The substrate transfer device of claim 13, wherein the detection part includes a light emitting member and a light receiving member disposed to be faced with each other in a vertical direction centering a path along with the first and the second substrates.

18. The substrate transfer device of claim 13, wherein the control part controls the first and the second transfer members based on the positions of the first and the second substrates detected by the detection part such that the positions of the first and the second substrates are moved to previously set positions.

19. The substrate transfer device of claim 13, wherein the first and the second transfer members rotate the first and the second substrates centering a common axis, respectively, and wherein the first and the second transfer members move the first and the second substrates in a horizontal direction.

20. The substrate transfer device of claim 13, wherein each of the first transfer member and the second transfer member has a multijoint structure.
